(19) United States
(12) Patent Application Publication
(10) Pub. No.: US 2009/0067123 A1
(43) Pub. Date: Mar. 12, 2009

(54) BAGGED ROLLABLE DISPLAY WITH IMPROVED LIFETIME

(76) Inventors: Hjalmar Edzer Ayco Huitema, Veldhoven (NL); Nicolaas Willem Schellingerhout, Veldhoven (NL)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(21) Appl. No.: 11/993,788

(22) PCT Filed: Jun. 27, 2006
(86) PCT No.: PCT/IB06/52139

§ 371 Date: Mar. 20, 2008

Related U.S. Application Data
(60) Provisional application No. 60/695,664, filed on Jun. 30, 2005.

(51) Int. Cl. H05K 7/00

(52) U.S. Cl. 361/679.01

(57) ABSTRACT

A flexible display has barrier or other protective layers which are attached to the display only along a seam, rather than being attached to a surface of the display. The protective layers form an envelope or bag, which may have different properties on each side of the display surface and may be filled with an inert gas or inert and optically compensating liquid. The durability and lifetime of the display are increased.

The invention relates to semiconductor devices made of polymer or other organic material, in particular to an apparatus and method for protecting a polymer electronics device.

Many electronic devices can now be made from organic materials to create a device that can flex or can even be bent or rolled. These materials include not only organic polymer based flexible substrates, but also semiconductor materials such as organic light emitting diodes (OLED's) and organic transistors and electro-optical materials such as electrophoretic materials. These electronic devices can, in particular, be display panels, which may be passive or may be active matrix displays. A display panel may be rollable, in that it can be coiled with a small radius, often 2 cm or less, in successive layers and pulled out or unfurled for use, for example from a housing, in particular a tubular housing. Other flexible display panels, if not rollable into a cylindrical space, may be capable of being wrapped around other components of the display itself or around or against another surface.

Organic-electronics or polymer-electronics based displays suffer from lifetime problems caused by external, environmental factors, such as physical damage from scratching or other abrasion and chemical changes from exposure to oxygen, moisture, radiation and other agents.

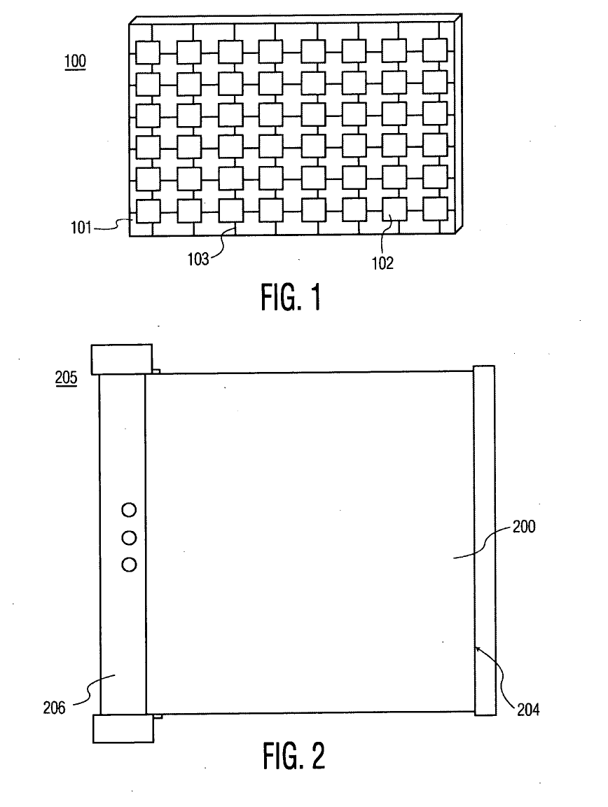

These problems are of particular concern with regard to rollable or wrapped displays. A rollable display, may be stored in a device or device housing, for example in a display “stick”, when not in use. The display screen can then be unrolled to provide the user with a large display. A display of this kind is shown in FIG. 1. For this to be possible, the Philips Electronics Polymer Vision business unit has developed a very thin (0.1 mm) flexible display that can be rolled up to a radius of 1 cm. The roll-up radius depends strongly on the total thickness of the display.

A common solution for solving these problems in some displays and other devices is adding a sufficiently impermeable and scratch-resistant barrier layer on a semiconductor substrate. An additional layer is, however, often not viable for displays which must be flexible or rollable, because the additional layer increases the stiffness and adds thickness to the display. For example, a layer of sealant material capable of holding a protective liquid such as that disclosed for an electroluminescent device in application no. EP-1022931 A1, published Jul. 26, 2000, presents this disadvantage.

Other ways have been disclosed for reducing the effects of external factors on flexible, rollable and other displays and devices having a polymer or other organic substrate. For example, application WO-2004/047059 A1 published Jun. 3, 2004 discloses a protection foil which is rolled up with a rollable display and unrolls with the display to provide a soft surface that protects the display from damage on a front side. Application IB2004/051846, published Apr. 7, 2005, discloses a rollable display protected from the air by being kept in a protective atmosphere while it is stored in a cylindrical housing, but exposed when it is in use. The protective atmosphere protects the display when it is stored inside the stick, but does not protect the display when it is in its rolled out position. These solutions are cumbersome and provide limited protection.

There is thus a need for a simpler, more effective apparatus and method to protect these flexible or rollable display devices as well as other organic substrates and other devices that may be subject to damage from external factors.

Accordingly, the present invention relates to an organic or polymer electronics device such as a display, display screen or display assembly, in which the effects of external factors are reduced, while avoiding disadvantages of the prior art.

In one aspect, the present invention provides a display, display screen or display assembly or other organic or polymer electronics device in which reductions in the lifetime of the display or other device which are caused by external factors, are significantly reduced.

In an embodiment of the current invention, a display screen is protected by sandwiching it between two flexible barrier layers sealed to each other, but which are not completely attached to the display. The display and the different layers may move independently, retaining the original flexibility of the display, but still improving its lifetime.

In another embodiment, a protective “bag” has a seal of short length extending in a single direction. For example, the bag may be sealed to a device, along a seam extending along an edge of the device or extending in an area of the device, leaving, for example, with respect to a rectangular, substantially planar display, a display end, two flat surfaces and two sides of the length of the display screen, all of which are free to move and thus contribute flexibility to the device.

According to one aspect of the present invention, a display screen or other flat panel device may extend partially out of a protective bag, to be able to connect electronically to other components, for example to a CPU or other processor. The bag and the device are sealed together to protect sensitive parts containing the polymer electronics from the environment.

In another aspect, a protective bag and a display may be connected to each other only along a single line, the different layers (the top layer of the bag, the display, and the bottom layer of the bag) are then able to move freely.

The bag may be filled with an inert gas (nitrogen) or an inert and optically compensating liquid. The latter has the advantage that it gives very good optical performance, as well as being nearly incompressible, preventing the top layer from “wrinkling”.

Additive materials may also be included in the bag or the liquid or substrate contained in it. For example, a getter may be kept in contact with a gas or other fluid or substrate within the protective bag to remove moisture or oxygen which was present during fabrication and remained in the protective bag when it was sealed or which may permeate into the protective bag during storage or use.

The current invention allows functions, such as protection, touch sensitivity and front lighting to be added to the display while keeping it sufficiently flexible.

These and other aspects of the invention will be apparent from and elucidated with reference to the embodiment(s) described hereinafter.

In the drawings:

FIG. 1 shows a flexible or rollable display screen.

FIG. 2 illustrates a rollable display screen and display stick used to store the display screen when it is not in use.

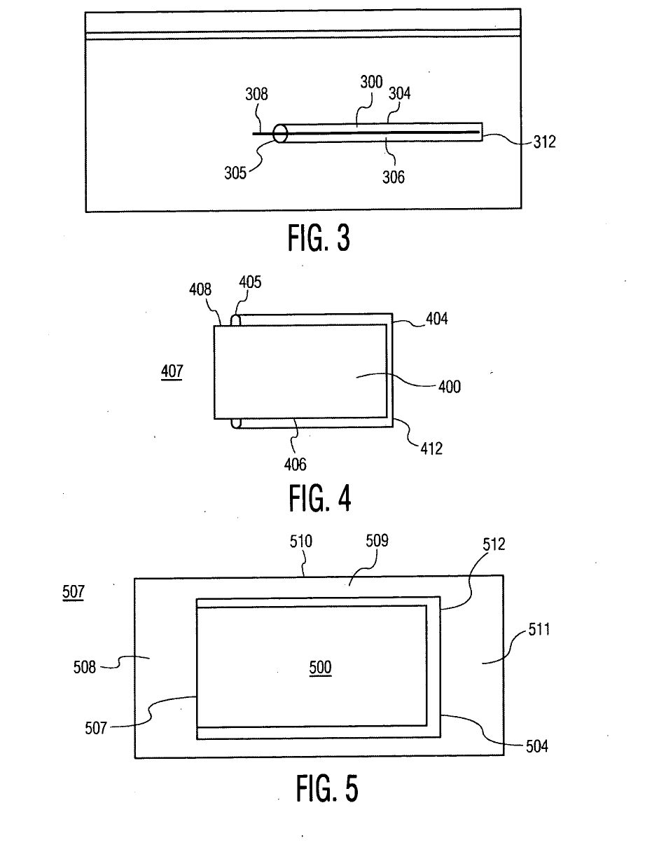

FIG. 3 is a sectional view of a flexible display screen in a protective “bag.”

FIG. 4 is a plan view of a flexible display screen in a protective “bag.”

FIG. 5 is a plan view of a wrapable display screen in a protective bag or envelope.

In the Figures, like reference numerals generally refer to like parts. The Figures are not drawn to scale.

FIG. 1 shows a display screen 100. The display screen 100 includes a substrate 101, a plurality of pixels 102 and a plurality of electrodes 103 connecting the pixels 102 to appropriate driver circuitry.

The substrate 101 may be a flexible substrate formed from an organic polymer or another suitable flexible material. The substrate may, for example, be made of a flexible polymer material, such as PET, PEN, polyurethane, polyester, polycarbonate or similar materials.

In the case of an active matrix array display device, the pixels 102 may include thin film transistors, which may be of an organic semiconductor material. The transistors may be any known suitable organic semiconductor material, such as a polythiophene derivative or a polyphenylvinylene derivative. The pixels have electro-optical display elements, such as organic liquid crystal material, organic semiconductor material such as a light emitting organic polymer or electrophoretic material. These organic materials are degradable upon exposure to an external environmental factor such as light, air or moisture, i.e., components made of these materials undergo unwanted chemical reactions as a result of their exposure to such factors. These components may also be soft or malleable and subject to damage from abrasion, handling or other physical contact or use.

FIG. 2 illustrates a display screen 200 in a rollable display 205. The rollable display 205 has a stick-type housing 206 containing drive electronics and including a controller or processor as well as a power source such as a battery, connectable via interconnecting pins on a pull-out grip (not shown) to an electronic apparatus such as a mobile telephone. The display screen 200 in FIG. 2 provides a large display in the unrolled position (as shown), and can be rolled into the housing 206 when not used, thus providing a small form factor when not in use, and yet a large display when unrolled for use.

FIG. 3 is a sectional view of a display assembly 307 including a flexible display screen 300 in a protective envelope or bag 304 in accordance with the present invention. The bag 304 and display screen 300 are sealed at a seam 305, here near an end 308 of the display screen 300 and extending in a direction substantially at a right angle to a length of the display screen 300. The protective bag 304 and seal 305 create an enclosed space 306 which is substantially hermetically sealed. The enclosed space 306 is sufficient to allow the display screen 300 some freedom of movement not only in the two dimensions of the display surface of the display screen 300, but also in three dimensions. The display assembly 307 in FIG. 3 is partially enclosed by the protective bag 304, having the end 308 outside the bag 304.

The bag 304 can be constructed in many different ways, for example, from a top layer with a protective and, optionally, a light-guiding function polarizing, filtering or similar function, and a bottom layer with a protective function as well as many possible additional features, such as touch sensitivity capability. The bag 304 may be constructed of any durable, thin polymer or other plastic film of low permeability, such as a polyurethane, polyester, polycarbonate or similar materials. The material of the bag 304 must be suitable as a barrier or protective layer or for supporting such a layer.

The bag 304 may sealed to the display screen 300 or otherwise to the display assembly 307 by, for example, a glue seal of an epoxy or a urethane adhesive or other compound or method, as known to one of ordinary skill in the art. Any way of sealing that will effect a seal without affecting the organic electronics of the display screen 300 may be used.

An envelope edge 312 of the protective bag or envelope 304 may be constructed so that it can compensate the length differences when the display is rolled up. For this purpose the envelope edge 312 must be sufficiently flexible. This can be achieved in many ways, e.g. by using a flexible sealant on the right-hand edge, allowing shearing, or by keeping the layers of the bag sufficiently thin, allowing tilting.

The seal may also be at least partly made of a metal. Thin metal layers can be applied at the position of the seal on both the substrate of the display screen 300 and the protective bag 304, outside the region of electrical contact. A metal seal, in particular, has a low permeability to water and oxygen. Metal layers can be made to form a seal by means such as. pressure bonding, soldering, laser welding or ultrasonic welding.

The enclosed space 306 may be filled with an inert gas such as nitrogen or argon or with an inert and optically compensating liquid. An optically compensating liquid may be chosen, for example, based on refiactive index, color, light absorption characteristics or bother properties in order to enhance operation of the display. The liquid may contain a plasticizer, stabilizer or other additives.

The enclosed space 306 or material of the bag 304 may contain a getter to remove moisture or oxygen or other reactive substances that may be left in the space 306 after manufacture or which may permeate into the space 306 during storage or operation of the display screen 300. The getter or getters may be, for example, a silica gel or a hydroscopic salt such as sodium chloride for moisture removal or a reactive metal alloy to remove oxygen, water, carbon dioxide and other impurities. The selection of a getter or getters to remove one variety or a number of kinds of impurities that would be encountered in a given display configuration is well known to one of ordinary skill in the art.

FIG. 4 illustrates in plan view a display assembly 407 of an embodiment of the present invention as shown in FIG. 3. The flexible display screen 400 is in an envelope or protective bag 404 which encloses a space 406 and is sealed along a seam 405 transverse to a length of the display screen 400. An end 408 of the display screen 400 extends outside the bag 404 and provides, for example, connection points for physical and electrical connection of the display assembly 407 to other components of the display. The end 408 may have a protective coating or barrier layer.

FIG. 5 is a plan view of a wrapable display screen 500 in a protective envelope or bag 504.

In the embodiment illustrated in FIG. 5, a display assembly 507 of the present invention employs a flexible, wrapable display screen 500 and a protective envelope or bag 504 integrated relative to a display section 509 of a display cover 510. An attachment section 508 of display cover 510 facilitates coupling of flexible display assembly 507 to a housing (such as 206 in FIG. 2) in any conventional manner. An optional control section 511 of the display cover 510 facilitates a construction of a keyboard or any other type of mechanism for controlling the display assembly 507 as needed.

The flexible display screen 500 is sealed at a seam 505 opposite an envelope edge 512 of the bag 504. The bag 504 may be secured to the display section 509, for example at the envelope edge 512. The display screen 500 may also be secured to the display section 509, for example, at two or more points along the seam 505. The display assembly 507 is then wrapable in that it may be folded around and unfolded from a housing. The display screen 500 remains enclosed in the protective bag 504 and secured by the protective bag 504 to the display section 509, but is free to move in directions transverse to the seam 505.

Although this invention has been described with reference to particular embodiments, it will be appreciated that many variations will be resorted to without departing from the spirit and scope of this invention as set forth in the appended claims.

The specification and drawings are accordingly to be regarded in an illustrative manner and are not intended to limit the scope of the appended claims.

In interpreting the appended claims, it should be understood that:

a) the word “comprising” does not exclude the presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function;

e) any of the disclosed elements may be comprised of hardware portions (e.g., including discrete and integrated electronic circuitry), software portions (e.g., computer programming), and any combination thereof;

f) hardware portions may be comprised of one or both of analog and digital portions;

g) any of the disclosed devices or portions thereof may be combined together or separated into further portions unless specifically stated otherwise; and

h) no specific sequence of acts is intended to be required unless specifically indicated.

1. A display device assembly comprising:
a display screen and
a protective bag enclosing all or part of the display screen,
the bag being sealed to the display device assembly along a seam.

2. The display device assembly claim 1 wherein the display screen has a surface extending in a first and a second direction and the seam extends in the first direction.

3. The display device assembly of claim 2 wherein one or more first edges of the display screen extend in the first direction, one or more second edges of the display screen extend in the second direction and two of the second edges of the display screen are not joined to the protective bag.

4. The display device assembly of claim 3 wherein at least one of the first edges is not joined to the protective bag.

5. The display device assembly of claim 1 wherein one or more first edges of the display screen extend in a first direction, one or more second edges of the display screen extend in a second direction and two or more surfaces of the protective bag are joined by a flexible sealant at an envelope edge opposite at least one of the first and second edges of the display screen.

6. The display device assembly of claim 1 wherein the seal extends only in the first direction.

7. The display device assembly of claim 1 comprising a getter exposed to an enclosed space within the bag.

8. The display device assembly of claim 1 wherein the display screen is flexible.

9. The display device assembly of claim 1 wherein the display screen is rollable.

10. The display device assembly claim 1 wherein the bag is attached to a display cover.

11. The display device assembly of claim 1 wherein an enclosed space within the bag contains an inert gas.

12. The display device assembly of claim 1 wherein an enclosed space within the bag contains an optically compensating liquid.

13. An electronic device comprising a semiconductor made from a carbon-based material and a protective bag enclosing all or part of the semiconductor, the semiconductor being on a substrate, the substrate being sealed to the protective bag along a seam.

14. The electronic device of claim 13 wherein the semiconductor is planar and the seam extends in a single direction with respect to a plane of the substrate.

15. A display comprising:
a display screen and
a protective bag enclosing all or part of the display screen,
the protective bag being sealed.

16. The display of claim 15, wherein the display extends in two or more directions and the protective bag is sealed to the display only along a seam extending substantially in only one of the two or more directions.
